(19) United States
(12) Patent Application Publication
(10) Pub. No.: US 2023/0187735 A1
(43) Pub. Date: Jun. 15, 2023

(54) THERMOELECTRIC GENERATOR IN A BATTERY PACK

(71) Applicant: MILWAUKEE ELECTRIC TOOL CORPORATION, Brookfield, WI (US)

(72) Inventor: Jiannan Tan, Irvine, CA (US)

(21) Appl. No.: 18/062,846

(22) Filed: Dec. 7, 2022

Related U.S. Application Data
(60) Provisional application No. 63/288,259, filed on Dec. 10, 2021.

(51) Int. Cl. H01M 10/6572; H02J 7/00; H10N 10/13; H10N 10/17; H01M 10/613; H01M 10/6235

(52) U.S. Cl. CPC H01M 10/6572; H02J 7/0068; H01L 35/30; H01L 35/32; H01M 10/613; H01M 10/6235; B25F 5/02

(57) ABSTRACT

Battery packs that include a housing, a plurality of rechargeable battery cells within the housing, and a plurality of thermoelectric generators. The plurality of thermoelectric generators are within the housing and are positioned proximate to and in thermal communication with the plurality of rechargeable battery cells.

### RELATED APPLICATIONS

This application claims the benefit of U.S. Provisional Patent Application No. 63/288,259, filed Dec. 10, 2021, the entire content of which is hereby incorporated by reference.

### FIELD

Embodiments described herein relate to battery packs.

### BACKGROUND

Devices such as battery packs can generate heat as a byproduct of providing energy to a connected device. For example, lithium ion battery packs may include a plurality of cells that generate heat during energy transfer.

### SUMMARY

Embodiments described herein relate to battery packs including thermoelectric generators to convert temperature differences within the battery pack to electricity that can be used by the battery pack.

Battery packs described herein include a housing, a plurality of rechargeable battery cells within the housing, and a plurality of thermoelectric generators. The plurality of thermoelectric generators are within the housing and are positioned proximate to and in thermal communication with the plurality of rechargeable battery cells.

Systems described here include a handheld power tool and a battery pack. The battery pack includes a housing, a plurality of rechargeable battery cells within the housing, and a plurality of thermoelectric generators. The plurality of thermoelectric generators are within the housing and are positioned proximate to and in thermal communication with the plurality of rechargeable battery cells.

Methods described herein for operating a battery pack including thermoelectric generators include coupling the battery pack including a plurality of battery cells and a plurality of the thermoelectric generators to a device, operating the device, causing heat waste to be generated proximate to the battery cells within the battery pack, converting, using the plurality of thermoelectric generators, a temperature difference provided by the heat waste into electricity, and transferring the electricity back to the battery pack.

Before any embodiments are explained in detail, it is to be understood that the embodiments are not limited in application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Other aspects of the embodiments will become apparent by consideration of the detailed description and accompanying drawings.

### BRIEF DESCRIPTION OF THE DRAWINGS

FIG. 1 is a perspective view of a handheld power tool, according to an embodiment of the disclosure.

FIG. 2 is a cross-sectional view of the handheld power tool of FIG. 1, according to an embodiment of the disclosure.

FIG. 3A is a perspective view of a thermoelectric generator, according to an embodiment of the disclosure.

FIG. 3B is a perspective view of a thermoelectric generator with a cutout section, according to an embodiment of the disclosure.

FIG. 4A is a perspective view of a battery pack, according to an embodiment of the disclosure.

FIG. 4B is a perspective view of battery cells from the battery pack of FIG. 4A, according to an embodiment of the disclosure.

FIG. 4C is a side view of the battery cells of FIG. 4B, according to an embodiment of the disclosure.

FIG. 4D is a top view of the battery cells of FIG. 4B, according to an embodiment of the disclosure.

FIG. 5A is a perspective view of a battery pack, according to an embodiment of the disclosure.

FIG. 5B is a perspective view of battery cells from the battery pack of FIG. 5A, according to an embodiment of the disclosure.

FIG. 5C is a side view of the battery cells of FIG. 5B, according to an embodiment of the disclosure.

FIG. 5D is a top view of the battery cells of FIG. 5B, according to an embodiment of the disclosure.

FIG. 6A is a perspective view of a battery pack, according to an embodiment of the disclosure.

FIG. 6B is an exploded view of the battery pack of FIG. 6A, according to an embodiment of the disclosure.

FIG. 7 illustrates a control system for the battery packs of FIGS. 1-6B, according to embodiments described herein.

FIG. 8 is a flow chart illustrating a process for operating the thermoelectric generators in a battery pack, according to some embodiments.

### DETAILED DESCRIPTION

Embodiments described herein relate to battery packs for use with any combination of power tools. For example, the battery packs can be lithium ion battery packs, including but not limited to battery packs with nominal voltages of 12V, 18V, 36V, 40V, 72V, 80V, etc. Similarly, the battery packs can be designed for use with different tools and with different connection types. For example, the battery packs can include stem type, rail type, etc., and can be battery packs for coupling to different power, outdoor, home, etc., tools. Regardless of the battery pack voltage and design, the lithium ion battery packs use a plurality of battery cells to store and discharge energy to a connected device. During charging and discharging of the battery cells, there can be a heat transfer during the respective chemical processes that take place within the cells. For the discharge reaction, an exothermic reaction can occur that produces heat waste. The present disclosure can implement one or more thermoelectric generators (“TEGs”) or Seebeck generators to utilize any heat waste to generate additional electrical energy for use by the battery packs and/or attached power tool or other device.

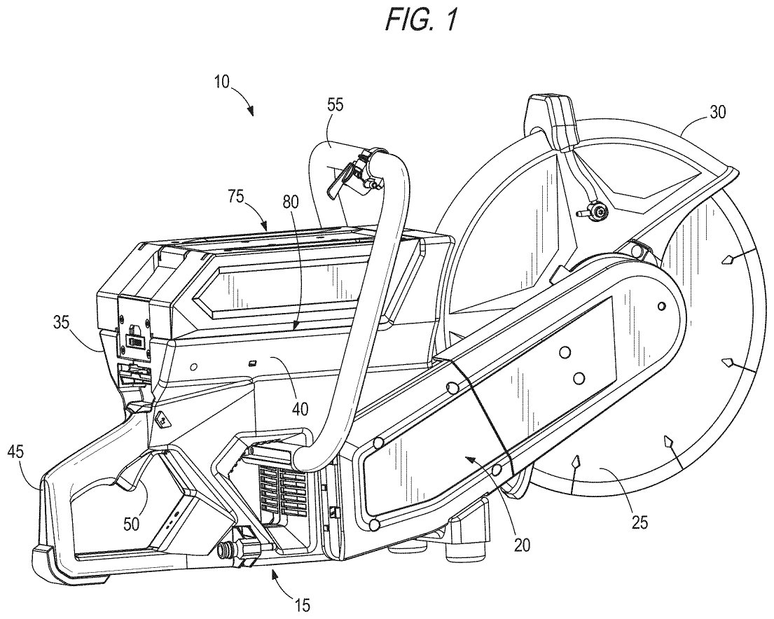

FIG. 1 illustrates a handheld power tool 10, which is a cut-off saw in an example embodiment. In other embodiments, the power tool 10 is a different type of power tool (e.g., an impact wrench, a hammer drill, an impact driver, a rotary hammer, etc.). The saw 10 includes a housing 15, a support arm 20 coupled to and extending from the housing 15, a cutting wheel 25 carried by the support arm 20, and a guard 30 covering a portion of the circumference of the cutting wheel 25. The illustrated housing 15 is a clamshell housing having left and right cooperating halves 35, 40. A first or rear handle 45 extends from a rear portion of the housing 15 in a direction generally opposite the support arm 20. A trigger 50 for operating the saw 10 is located on the rear handle 45. In some embodiments, the trigger 50 can provide an activation mechanism for powering on the saw 10. In the illustrated embodiment, the saw 10 also includes a second or forward handle 55 that wraps around an upper portion of the housing 15. The forward handle 55 and the rear handle 45 provide grip areas to facilitate two-handed operation of the saw 10. The cutting wheel 25 can be a blade, an abrasive disk, or any other rotatable element capable of removing material from a workpiece.

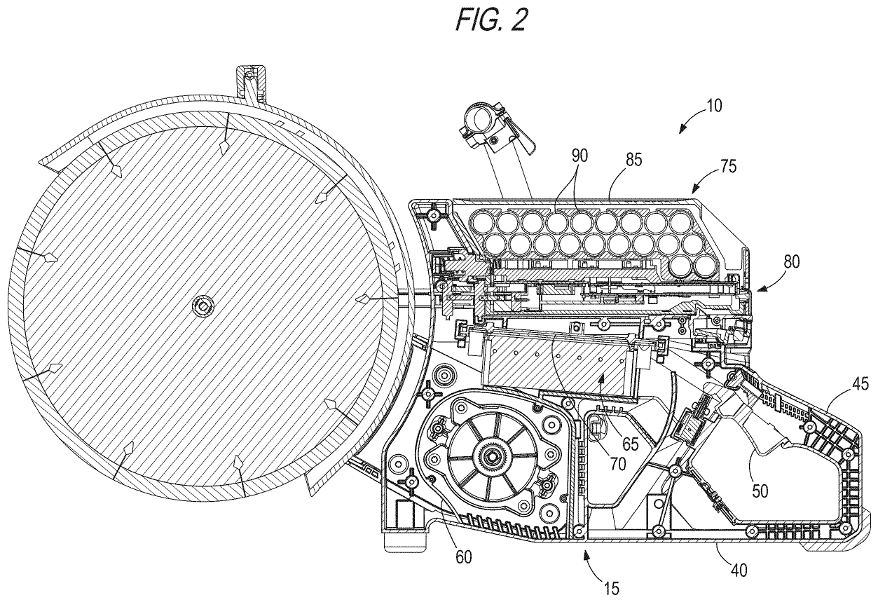

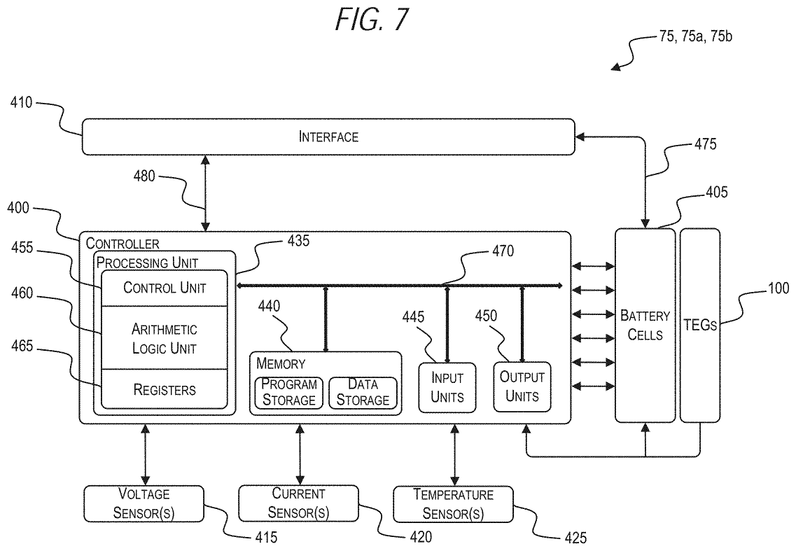

Referring to FIG. 2, the saw 10 further includes a motor housing 60 formed within the housing 15 at a front, lower portion of the housing 15. An electric motor (see FIG. 7) is mounted in the motor housing 60. The motor is preferably a brushless direct-current (“BLDC”) motor. Operation of the motor is governed by a motor control system 65 including a printed circuit board (“PCB”) 70. In some embodiments, the motor control system 65 can be coupled to a switch to receive a signal for operating the motor in a forward direction or a reverse direction. The switch can include any combination of switch types, switch mechanisms, locations, etc. without departing from the scope of the present invention.

In some embodiments, the illustrated saw 10 is a cordless electric saw and includes a battery pack 75 that provides power to the motor. The battery pack 75 is removably coupled to a battery pack receptacle 80, which is located on the upper portion of the housing 15 in the illustrated embodiment (see FIG. 1). As such, the forward handle 55 at least partially surrounds the battery pack receptacle 80 and the battery pack 75, when the battery pack 75 is coupled to the battery pack receptacle 80. The illustrated battery pack 75 is a power tool battery pack and includes a battery pack housing 85 and a plurality of rechargeable battery cells 90, as shown in FIG. 2, disposed within the battery pack housing 85. The battery cells 90 are lithium-based battery cells having a chemistry of, for example, lithium-cobalt (“Li—Co”), lithium-manganese (“Li—Mn”), or Li—Mn spinel. In some embodiments, the battery cells 90 have other suitable lithium or lithium-based chemistries, such as a lithium-based chemistry that includes manganese, etc. The battery cells 90 within the battery pack 75 provide operational power (e.g., voltage and current) to the handheld power tool 10. The battery cells 90 may have different nominal voltages, such as, for example, between 3.6V and 4.2V. Likewise, the battery pack 75 may have different nominal voltages, such as, for example, 10.8V, 12V, 14.4V, 21V, 24V, 28V, 36V, 60V, 80V, between 10.8V and 80V, etc. The battery cells 90 also each have a capacity of, for example, approximately between 1.0 ampere-hours (“Ah”) and 6.0 Ah. In exemplary embodiments, the battery cells 90 each have capacities of approximately, 1.5 Ah, 2.4 Ah, 3.0 Ah, 4.0 Ah, 6.0 Ah, between 1.5 Ah and 6.0 Ah, etc. In the illustrated embodiment, the battery pack 75 has a nominal output voltage of about 80V. In other embodiments, the battery pack 75 can have a different nominal voltage, such as, for example, 36V, 40V, 72V, between 36V and about 80V, or greater than 40V. The present disclosure is not limited to use with lithium battery cells 90, it can alternatively be implemented with batteries using any other suitable chemistry. Similarly, the present disclosure is not limited to use with the saw 10, but can be implemented using any combination of battery operated devices.

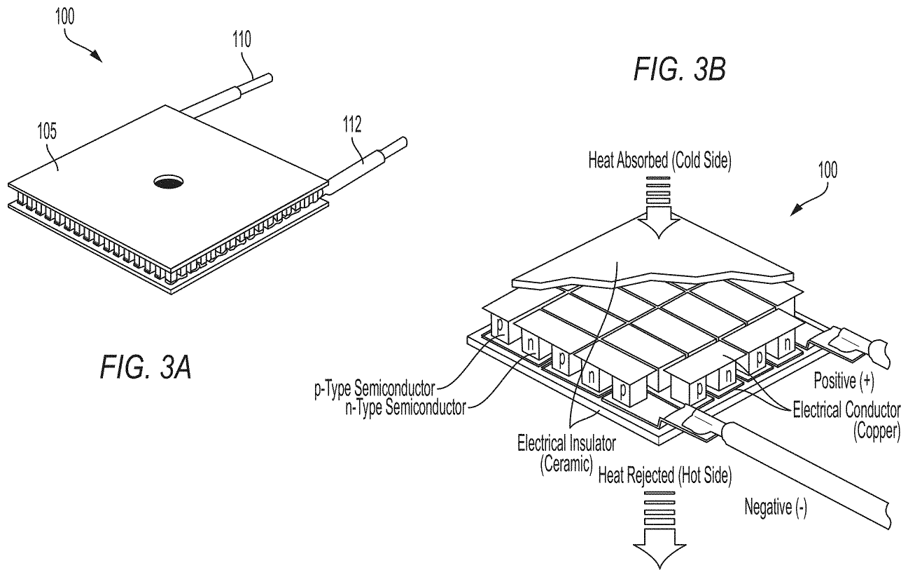

Referring to FIGS. 3A and 3B, in some embodiments, the battery packs 75 can be designed to include one or more thermoelectric generators (“TEGs”) 100 or Seebeck generators to transform any heat waste generated by the battery cells (or other battery pack components) into electricity. A TEG 100 module includes two dissimilar thermoelectric materials joined at their ends including an n-type (with negative charge carriers) and a p-type (with positive charge carriers) semiconductor. These thermoelectric materials generate power directly from temperature differences at their respective ends by converting the temperature differences into electric voltage. The temperature gradient between the opposing hot and cold faces of the TEG 100 is the driving force for the energy conversion. Thus, in the present disclosure, the TEGs 100 can be used to convert waste heat energy into electrical energy using compact and light-weight designs while producing no additional noise. Additionally, the TEGs 100 are solid-state structures that are highly reliable with 100,000 plus hours of life, providing a zero-carbon green footprint. The TEGs 100 can also be implemented using stand-alone solutions with no need for any liquid, refrigerants, plumbing lines, valves, pumps, or compressors. The TEGs 100 can include, be combined with, and/or replaced with any combination of devices that are designed to convert temperature increases or temperature differences into electrical energy.

In some embodiments, the TEGs 100 of the battery packs 75 can be configured to cool or control the temperature of the battery packs 75 by transferring heat waste generated by the battery cells (or other battery pack components) from one side of the TEGs 100 to the other (e.g., operate as thermoelectric coolers). Cooling occurs when a current passes through one or more pairs of elements from, for example, an n-type semiconductor to a p-type semiconductor. There is then a corresponding decrease in temperature at the junction (“cold side”), resulting in the absorption of heat from the environment. The heat is carried along the elements by electron transport and released on the opposite (“hot”) side as the electrons move from a high-energy state to a low-energy state. In some embodiments, the cooling effect of the TEGs 100 is proportional to the number of coolers used.

FIG. 3A depicts an example TEG 100 device having a housing 105 with two electrical leads 110, 112 for transferring electrical power out. The housing 105 can include two planar surfaces or faces that are separated by thermoelectric structures that generate power directly from heat by converting temperature differences to electric voltage, as discussed in greater detail herein. The two electrical leads can be a positive lead 110 and a negative lead 112. The TEG 100 device can include any combination of TEG sizes, shapes, wattage, etc. For example, the TEG 100 can be a 30 mm×30 mm×5 mm module that is rated for 5 Watts.

Referring to FIG. 3B, in some embodiments, the TEG 100 can be constructed from a multilayer design. FIG. 3B depicts an example TEG 100 device with a portion of the housing 105 cut away to show the internal semiconductors situated between the opposing housing 105 parts. The housing 105 can include an electrical insulator layer, for example, a ceramic layer adjacent to electrical conductor layers (e.g., copper). One of the copper layers can be coupled to the positive lead 110 and another to the negative lead 112 to provide the electrical output. Situated between the copper layers for each housing 105 part can be a plurality of semiconductors for implementing the Seebeck effect. For example, the TEG 100 can include a plurality of alternating p-type semiconductors (with positive charge carriers) and n-type semiconductor devices (with negative charge carriers). The alternating p-type semiconductors and n-type semiconductor devices can be organized in a grid patterns, for example, as depicted in FIG. 3B. Direct electric current will flow in the circuit when there is a temperature difference between the ends of the semiconductor materials. With such a configuration, as one surface of the TEG 100, for example a top surface, is exposed to heat, it will transfer through the first conductive layer to the semiconductors which will generate an electrical output (e.g., current) through the second conductive layer to the leads 110, 112.

In some embodiments, the one or more TEGs 100 can be positioned within the battery pack housing 85 at strategic locations to best leverage the thermoelectric properties of the TEGs 100. For example, the TEGs 100 can be coupled to or near the rechargeable battery cells 90 using any combination of fasteners, adhesives, friction fits, etc. The energy transformed by the TEGs 100 can then be passed back into the battery cell(s) 90 to increase efficiency or run time of the battery packs 75 during use, for example, increasing length for which the battery packs 75 will power a handheld power tool 10 or other device. In some implementations, the TEGs 100 move heat away from the battery cell(s) 90 to increase efficiency or run time of the battery packs 75 during use.

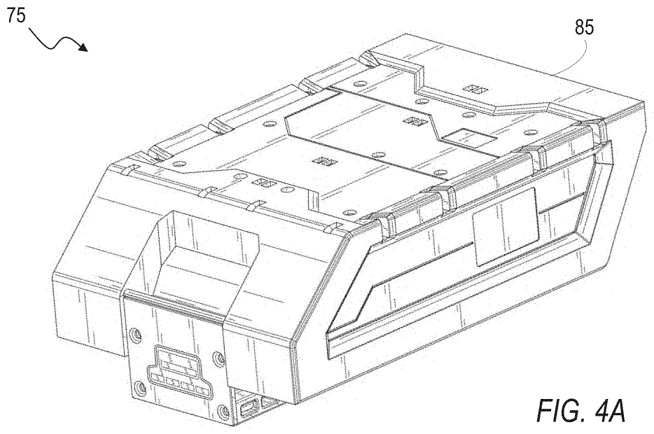

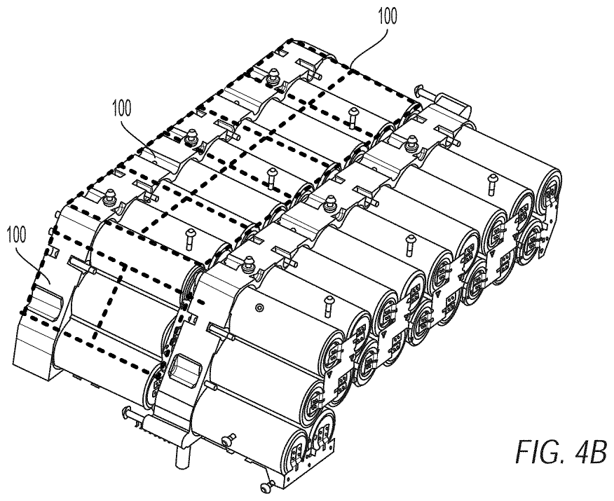

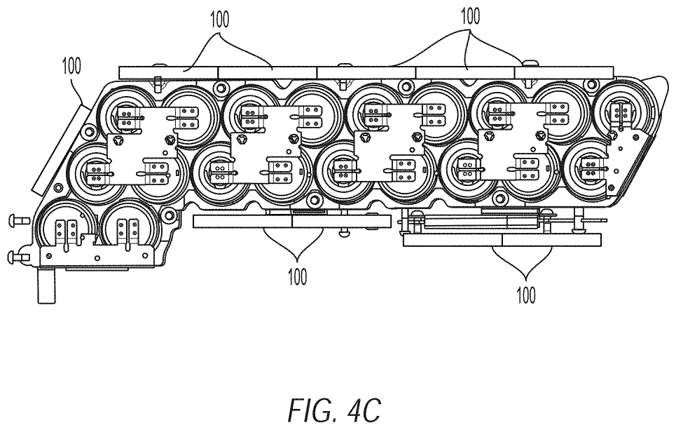

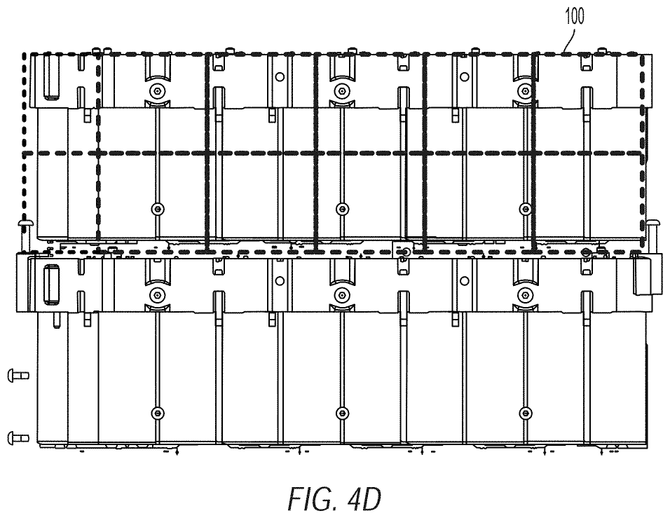

Referring to FIGS. 4A-4D, a battery pack 75 for use with a power tool, such as the saw 10 discussed with respect to FIGS. 1 and 2, is depicted. In some embodiments, the battery pack 75 can be designed to include a plurality of TEGs 100 within the battery pack housing 85. FIG. 4A shows a battery pack 75 for use with the saw 10 or another power tool needing a larger power supply. The larger battery pack 75 depicted in FIG. 4A can include a larger amount of rechargeable battery cells 90 to provide a larger voltage supply, for example, 80V. As shown in FIG. 4B, the battery pack 75 can include forty rechargeable battery cells 90. In some embodiments, the plurality of TEGs 100 can be situated around the outer surface of the rechargeable battery cells 90 (e.g., in thermal communication with the battery cells 90) at different locations between the rechargeable battery cells 90 and the inside portion of the housing 85. The size, shape, and position of the grouped together rechargeable battery cells 90 may dictate how many TEGs 100 can be included within the battery pack 75.

Referring to FIGS. 4B-4D, the rechargeable battery cells 90 can be sized and arranged such that the battery pack 75 can include forty TEG 100 modules (sized at about 30 mm×30 mm×5 mm). For example, as shown in the side view of the battery pack 75 in FIG. 4C, the battery pack 75 can have an upper surface length of about 180 mm such that it will accommodate five TEG 100 modules along its upper surface. The battery pack 75 can have a bottom surface of about 135 mm in length such that it will accommodate four TEG 100 modules along its bottom surface. Lastly, the battery pack 75 can include a front face surface that is about 45 mm such that it will accommodate one TEG 100 module along a length of its face surface. In some instances, there may be surface areas of the battery pack 75 that cannot accommodate any TEG 100 modules. For example, as shown in FIG. 4C, the rear face and second lower front face may only measure about 22.5 mm in length such that they would not be able to accommodate a 30 mm×30 mm TEG 100 module. In some embodiments TEGs 100 of different sizes can be used (e.g., smaller or larger than 30 mm]. Additionally, as shown in FIG. 4D, the battery pack 75 can include two rows of the rechargeable battery cells 90 with each row measuring about 70 mm wide such that such that the battery pack 75 will accommodate four TEG 100 modules along its width. Therefore, a battery pack 75 having forty rechargeable battery cells 90 in this configuration can accommodate up to forty TEG 100 modules. Although the battery pack 75 depicted in FIGS. 4A-4D can accommodate up to forty TEG 100 modules, it would not necessarily need to be designed with forty TEG 100 modules. For example, a smaller number or larger number of TEG 100 modules could be implemented at select locations that have the highest temperature gradients.

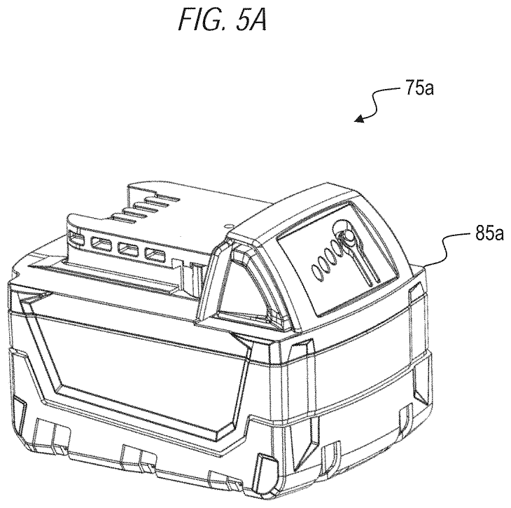

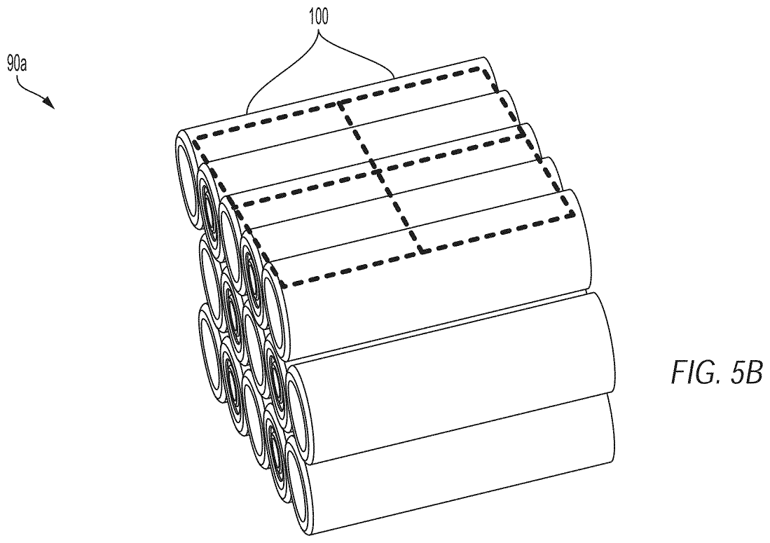

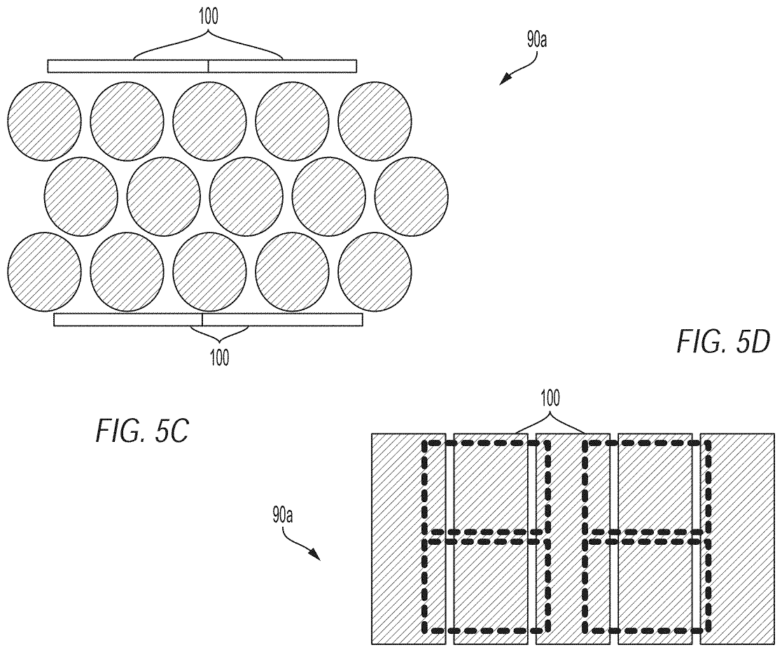

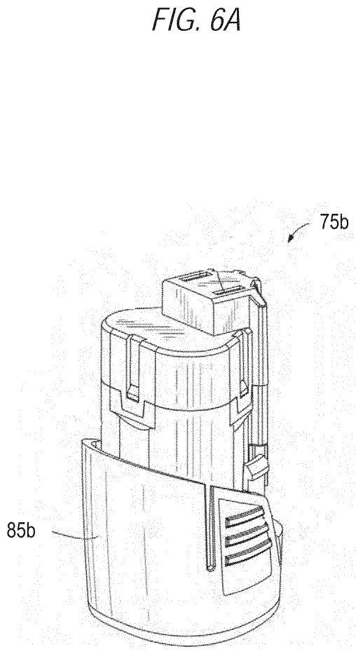

Referring to FIGS. 5A-5D, a battery pack 75a for use with lower voltage power tools such as 18V drills, fasteners, saws, pipe cutters, sanders, nailers, staplers, vacuum cleaners, blowers, etc., is depicted. The battery pack 75a can include a lower number of rechargeable battery cells 90a than as discussed with respect to FIGS. 1-4D. For example, as depicted in FIG. 5B, a housing 85a can include fifteen rechargeable battery cells 90a for a 9 Ah battery pack 75. The battery cells 90a are configured in a series-parallel arrangement of five sets of three series-connected cells. A similar battery pack design can be implanted with ten rechargeable battery cells 90a arranged in two rows of five. In some embodiments, the plurality of TEGs 100 can be situated around the rechargeable battery cells 90a (e.g., in thermal communication with the battery cells 90a) at different locations between the rechargeable battery cells 90a and the inside portion of the housing 85a. The size and shape of the grouped together rechargeable battery cells 90a may dictate how many TEGs 100 can be included within the battery pack 75a.

Referring to FIGS. 5B-5D, the surface area of the battery pack 75a is about 65 mm wide by 78 mm long with a combination of vertical faces of about 54 mm each. Using the same example TEG 100 dimensions of 30 mm×30 mm×5 mm discussed above, the battery pack 75a could fit eight to twelve TEG 100 modules on the surfaces of the fifteen rechargeable battery cells 90a. For example, each of the bottom and the top surfaces could include a 2×2 arrangement of TEGs 100, as outlined in FIGS. 5B-5D.

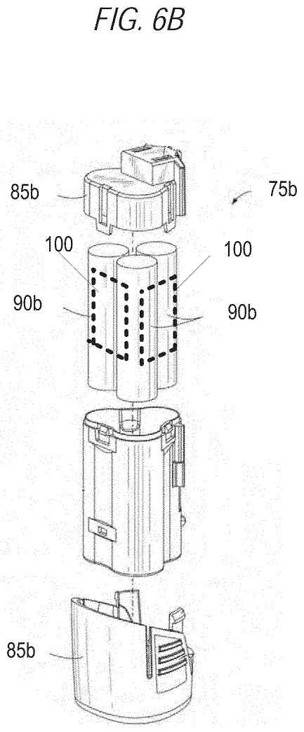

FIGS. 6A and 6B illustrate a battery pack 75b connectable to and supportable by hand-held power tools, such as 12V power drills, fasteners, saws, pipe cutters, sanders, nailers, staplers, vacuum cleaners, blowers, etc. The battery pack 75b is also connectable to and supportable by outdoor power tools such as string trimmers, hedge trimmers, blowers, chain saws, etc. As shown in FIGS. 6A and 6B, the battery pack 75b includes a housing 85b and one or more rechargeable battery cells 90b (shown in FIG. 6B) supported by the housing 85b. The battery cells 90b can be arranged in series, parallel, or a series-parallel combination. For example, the battery pack 75b can include a total of three battery cells 90b configured in a series arrangement. In the illustrated embodiment, the battery cells 90b are arranged in series, and each battery cell 90b has a nominal voltage of approximately 3.6V-4.2V, such that the battery pack 75b has a nominal voltage of approximately twelve volts (12V). In some embodiments, the plurality of TEGs 100 can be situated around the rechargeable battery cells 90b (e.g., in thermal communication with the battery cells 90b) at different locations between the rechargeable battery cells 90b and the inside portion of the housing 85b.

The illustrated battery cells 90, 90a, and 90b are, for example, cylindrical 18650 battery cells (18 mm diameter and 65 mm length), such as the INR18650-15M lithium-ion rechargeable battery cell manufactured and sold by Samsung SDI Co., Ltd. of South Korea. In other embodiments, the battery cells 90b are, for example, cylindrical 14500 battery cells (14 mm diameter and 50 mm length), 14650 battery cells (14 mm diameter and 65 mm length), 17500 battery cells (17 mm diameter and 50 mm length), 17670 battery cells (17 mm diameter and 67 mm length), 18500 battery cells (18 mm diameter and 50 mm length), 26650 battery cells (26 mm diameter and 65 mm length), 26700 battery cells (26 mm diameter and 70 mm length), etc. Each battery cell 90b can be generally cylindrical and can extend along a cell axis parallel to the cylindrical outer cell wall.

Battery packs 75, 75a, 75b, discussed with respect to FIGS. 3A-6B provide examples of some battery pack designs that may be used to implement the thermoelectric generators in accordance with the present disclosure. However, other combinations of battery cells are also contemplated. For example, in other embodiments, the battery pack 75 may include a different number of battery cells 90 and/or battery cells 90 arranged in different geometries with different numbers of rows/groupings. Additionally, the cells 90 may be organized in any combination of manners, which may be connected in series, parallel, or a series-parallel combination in order to produce a battery pack having a desired combination of nominal battery pack voltage and battery capacity.

FIG. 7 illustrates a control system for implementing the battery packs 75, 75a, 75b discussed herein with the handheld power tool 10. The control system includes a controller 400. The controller 400 is electrically and/or communicatively connected to a variety of modules or components of the battery pack 75, 75a, 75b. For example, the illustrated controller 400 is connected to one or more battery cells 405 and an interface 410. The controller 400 is also connected to one or more voltage sensors or voltage sensing circuits 415, one or more current sensors or current sensing circuits 420, one or more temperature sensors or temperature sensing circuits 425, and the TEGs 100. The controller 400 includes combinations of hardware and software that are operable to, among other things, control the operation of the battery pack 75, 75a, 75b, monitor a condition of the battery pack 75, 75a, 75b, enable or disable charging of the battery pack 75, 75a, 75b, enable or disable discharging of the battery pack 75, 75a, 75b, etc.

The controller 400 includes a plurality of electrical and electronic components that provide power, operational control, and protection to the components and modules within the controller 400 and/or the battery pack 75, 75a, 75b. For example, the controller 400 includes, among other things, a processing unit 435 (e.g., a microprocessor, a microcontroller, or another suitable programmable device), a memory 440, input units 445, and output units 450. The processing unit 435 includes, among other things, a control unit 455, an arithmetic logic unit (“ALU”) 460, and a plurality of registers 465 (shown as a group of registers in FIG. 7), and is implemented using a known computer architecture (e.g., a modified Harvard architecture, a von Neumann architecture, etc.). The processing unit 435, the memory 440, the input units 445, and the output units 450, as well as the various modules or circuits connected to the controller 400 are connected by one or more control and/or data buses (e.g., common bus 470). The control and/or data buses are shown generally in FIG. 7 for illustrative purposes. The use of one or more control and/or data buses for the interconnection between and communication among the various modules, circuits, and components would be known to a person skilled in the art in view of the invention described herein.

The memory 440 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 435 is connected to the memory 440 and executes software instructions that are capable of being stored in a RAM of the memory 440 (e.g., during execution), a ROM of the memory 440 (e.g., on a generally permanent basis), or another non-transitory computer readable medium such as another memory or a disc. Software included in the implementation of the battery pack 75, 75a, 75b can be stored in the memory 440 of the controller 400. The software includes, for example, firmware, one or more applications, program data, filters, rules, one or more program modules, and other executable instructions. The controller 400 is configured to retrieve from the memory 440 and execute, among other things, instructions related to the control processes and methods described herein. In other constructions, the controller 400 includes additional, fewer, or different components.

The interface 410 includes a combination of mechanical components (e.g., rails, grooves, latches, etc.) and electrical components (e.g., one or more terminals) configured to and operable for interfacing (e.g., mechanically, electrically, and communicatively connecting) the battery pack 75, 75a, 75b with another device (e.g., a power tool, a battery pack charger, etc.). For example, the interface 410 is configured to receive power via a power line 475 between the one or more battery cells 405 and the interface 410. The interface 410 is also configured to communicatively connect to the controller 400 via a communications line 480.

The controller 400 is configured to determine whether a fault condition of the battery pack 75, 75a, 75b is present and generate one or more control signals related to the fault condition. For example, the controller 400 is configured to detect an overvoltage condition of the one or more battery cells 405, and under voltage condition of the one or more battery cells 405, an over current condition (e.g., during charging or discharging), or an over temperature condition (e.g., during charging or discharging). If the controller 400 detects one or more fault conditions of the battery pack 75, 75a, 75b or determines that a fault condition of the battery pack no longer exists, the controller 200 is configured to provide information and/or control signals to another component of the battery pack 75, 75a, 75b (e.g. the interface 210, etc.).

In operation, the one or more TEGs 100 are integrated within a battery pack housing 85, 85a, 85b of the battery pack 75, 75a, 75b. A TEG 100 module is a solid-state structure device that converts temperature difference caused by heat waste directly into electrical energy through a physical process called the Seebeck effect. In some embodiments, the TEG 100 modules are placed proximate to at least one rechargeable battery cell 90, 90a, 90b, 405 within the battery pack 75, 75a, 75b. While the battery pack 75, 75a, 75b is discharging, for example, by using a tool coupled to the battery pack 75, 75a, 75b, increased temperature (e.g., waste energy causes by cell discharge) at or around the at least one rechargeable battery cell 90, 90a, 90b, 405 increases causing a temperature differential between the two sides of the one or more TEG 100 modules. The temperature gradient between the hot (e.g., face adjacent a battery cell 90, 90a, 90b) and cold faces (e.g., faces opposite of the battery cells 90, 90a, 90b) of TEG 100 module is the driving force for the energy conversion. In particular, thermoelectric materials that have both high electrical conductivity and low thermal conductivity will cause a direct electric current to flow in the circuit when there is a temperature difference between the ends of the materials.

In some embodiments, the TEG 100 modules can be placed over some or all available surface area of the grouped rechargeable battery cells 90, 90a, 90b. For example, the TEG 100 modules can be placed on a top, bottom, front, back, sides, of a group of rechargeable battery cell 90, 90a, 90b, where sufficient space is provided to fit one of the surfaces of the TEG 100. The TEGs 100 can be arranged substantially adjacent to one another or spaced out from one another, depending on the desired effect. For example, the TEGs 100 can be placed such that they are positioned side to side and touching, they can be placed with gaps therebetween, or a combination thereof. In some embodiments, the TEGs 100 can be positioned at different locations within the battery pack 75, 75a, 75b. For example, the TEGs 100 can be positioned between cells 90, 90a, 90b within the group of cells or adjacent to any other heat generating sources within the battery pack. In some embodiments, the TEGs 100 are bent or bendable and can be contoured around the outer cylindrical case of the battery cells 90, 90a, 90b.

The TEGs 100 can be wired to provide electrical energy back to the battery pack 75, 75a, 75b, the controller 400, and/or the handheld power tool 10. Each of the TEG 100 modules can have their own positive and negative leads which can be wired according to a preferred design. For example, the TEGs 100 can be wired together in series, parallel, or to a bus or other electrical communication pathway. Alternatively, the TEGs 100 can each be separately wired to a desired energy output. For example, each of the TEGs 100 can be individually wired to a different respective cell(s) 90, 90a, 90b or conductive pathways to provide electrical energy to those cells 90. Depending on how the TEGs 100 are wired, the electrical energy created by the TEGs 100 will be provided to particular components of the battery pack 75, 75a, 75b. For example, the TEG 100 modules can be wired such that they provided electrical energy back to charge the rechargeable battery cells 90 (as shown in FIG. 7). In some embodiments, the TEG 100 modules can be wired to provide energy to the attached handheld power tool 10 to operate some aspect of the tool. For example, electrical energy provided by the TEGs 100 can be used to power one or more peripherals (e.g., LEDs) of the power tool 10.

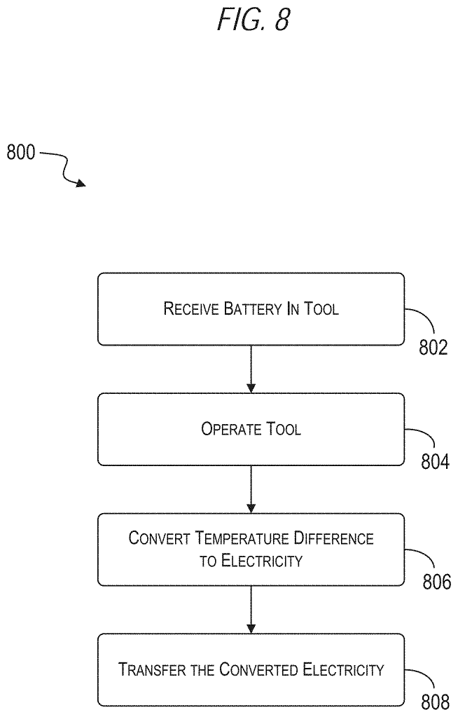

FIG. 8 is a process 800 for operating thermoelectric generators in a battery pack, such as the battery packs 75, 75a, 75b. The process 800 begins with coupling the battery pack, including the thermoelectric generator(s) 100 to a device, as discussed with respect to FIGS. 1-7 (STEP 802). The battery pack is, for example, the battery pack 75 and the device can be the handheld power tool 10. Thereafter, the handheld power tool 10 can be operated by a user (STEP 804), which would cause heat waste to be generated proximate to the battery cells 90 within the battery pack 75. As the battery cells 90 heat up a temperature difference will occur at opposing sides of the TEGs 100 positioned proximately to the battery cells 90 (e.g., in thermal communication with the battery cells 90). As the temperature difference reaches a certain point, the TEG 100 will convert the temperature difference, as discussed herein, into electrical energy (STEP 806). Thereafter, any electrical energy generated by the TEGs 100 will be transferred back to the battery pack 75 for storage or for powering the controller 400 or handheld power tool 10 (STEP 808). The energy provided by the TEGs 100 can then be used to prolong usage of the handheld power tool 10. In some embodiments, the TEGs 100 similarly produce energy when the battery pack 75, 75a, 75b is being charged.

The TEG harvesting efficiency is largely determined by the difference in temperature between the hot and cold faces. For example, the temperature difference between faces can be a temperature difference of about 25 C to 30C between cells and ambient, which drives an output power of about 0.2 W to 0.3 W per TEG module, which can be stacked up to about 2 W to 12 W range. TEG efficiency may range anywhere from 5% to 8% and up to 15%, based on which thermoelectric materials are being used. The efficiency of the TEGs can be increased by a combination of the thermoelectric material selections and the difference in temperature between faces. The TEGs should be configured, for example, such that they create a 10%-20% improvement for the battery pack operation. Additionally, the number of TEGs 100 in a battery pack 75 can dictate how much energy is generated from heat waste, such that larger battery packs may have more TEGs and thus have more energy being recycled to extend tool runtime.

Thus, embodiments described herein provide battery packs having thermoelectric generators. Various features and advantages are set forth in the following claims.

What is claimed is:

1. A battery pack comprising:
a housing;
a plurality of rechargeable battery cells within the housing; and
a plurality of thermoelectric generators within the housing and positioned proximate to and in thermal communication with the plurality of rechargeable battery cells.

2. The battery pack of claim 1, wherein each of the plurality of thermoelectric generators include a first face, a second face, and a plurality of semiconductors between the first face and the second face.

3. The battery pack of claim 2, wherein the plurality of semiconductors include a combination of p-type semiconductors and n-type semiconductors.

4. The battery pack of claim 1, wherein each of the plurality of thermoelectric generators includes at least one conductive layer.

5. The battery pack of claim 4, wherein each of the plurality of thermoelectric generators includes a positive lead and a negative lead coupled to the at least one conductive layer.

6. The battery pack of claim 5, wherein the positive lead and the negative lead are electrically coupled to at least one of the plurality of rechargeable battery cells.

7. The battery pack of claim 1, wherein the battery pack has a nominal voltage of up to 80V and the plurality of thermoelectric generates includes at least 40 thermoelectric generators.

8. The battery pack of claim 1, wherein the battery pack has a nominal voltage of up to 18V and the plurality of thermoelectric generates includes at least 8 thermoelectric generators.

9. The battery pack of claim 1, wherein the plurality of thermoelectric generators are configured to operate as thermoelectric coolers to transfer heat away from the plurality of rechargeable battery cells.

10. A system comprising:
a handheld power tool; and
a battery pack comprising:
a housing,
a plurality of rechargeable battery cells within the housing, and
a plurality of thermoelectric generators within the housing and positioned proximate to and in thermal communication with the plurality of rechargeable battery cells.

11. The system of claim 10, wherein each of the plurality of thermoelectric generators include a first face, a second face, and a plurality of semiconductors between the first face and the second face.

12. The system of claim 11, wherein the plurality of semiconductors include a combination of p-type semiconductors and n-type semiconductors.

13. The system of claim 10, wherein each of the plurality of thermoelectric generators includes at least one conductive layer.

14. The system of claim 13, wherein each of the plurality of thermoelectric generators includes a positive lead and a negative lead coupled to the at least one conductive layer.

15. The system of claim 14, wherein the positive lead and the negative lead are electrically coupled to at least one of the plurality of rechargeable battery cells.

16. The system of claim 10, wherein the battery pack has a nominal voltage of up to 80V and the plurality of thermoelectric generates includes at least 40 thermoelectric generators.

17. The system of claim 10, wherein the battery pack has a nominal voltage of up to 18V and the plurality of thermoelectric generates includes at least 8 thermoelectric generators.

18. The system of claim 10, wherein the battery pack has a nominal voltage of up to 12V and the plurality of thermoelectric generates includes at least 3 thermoelectric generators.

19. A method for operating a battery pack including thermoelectric generators, the method comprising:
coupling the battery pack to a device, the battery pack including a plurality of battery cells and a plurality of the thermoelectric generators;
operating the device to cause heat waste to be generated proximate to the plurality of battery cells;
converting, using the plurality of thermoelectric generators, a temperature difference provided by the heat waste into electricity; and
transferring the electricity back to the battery pack.

20. The method of claim 19, wherein the plurality of thermoelectric generators includes at least 8 thermoelectric generators.
